(19) United States
(12) Patent Application Publication
(10) Pub. No.: US 2020/0109473 A1
(43) Pub. Date: Apr. 9, 2020

(54) High throughput vacuum deposition sources and system thereof

(71) Applicant: Ascentool, Inc., Palo Alto, CA (US)

(72) Inventor: George Xinsheng Guo, Palo Alto, CA (US)

(21) Appl. No.: 16/582,068

(22) Filed: Sep. 25, 2019

Related U.S. Application Data
(60) Provisional application No. 62/742,822, filed on Oct. 8, 2018.

(51) Int. Cl. C23C 16/50; C23C 16/54

(52) U.S. Cl. CPC C23C 16/50; C23C 16/545

(57) ABSTRACT

A high throughput deposition apparatus includes a vacuum chamber comprising a first processing chamber, a plurality of elongated deposition sources in parallel in the first processing chamber, wherein each of the elongated deposition sources can include a gas distribution channel that provides a deposition material in a gas form, and an electrode configured to generate a plasma in the deposition material, and a web transport mechanism configured to move a plurality of workpiece webs passing by the elongated deposition sources in the first processing chamber. The plurality of workpiece webs are parallel to each other and are configured to receive the deposition material in the first process chamber.

### BACKGROUND OF THE INVENTION

The present application relates to material deposition technologies, and more specifically to high throughput deposition apparatus.

Vacuum depositions such as sputtering, chemical vapor deposition (CVD), or plasma enhanced chemical vapor deposition (PECVD) are used in many industries to deposit materials on workpieces such as web, glass, semiconductor wafers, hard disks, et al.

For material depositions on rectangular shaped workpieces and webs, PECVD is often applied between parallel plates to achieve good uniformity. One challenge for parallel-plate PECVD is the relative low plasma density and low densities of reactive species, which require relatively high process pressures to maintain stable plasma. The higher process pressure leads to low ionization efficiency and high rate of reactions in gas phase, resulting in low material utilization, powder formation and expensive waste gas treatment system. Another challenge for PECVD is deposition on the plasma sources, which can lead to particulates formation, clogging of gas distribution holes, and change in plasma conditions. The in-situ cleaning of the plasma sources not only takes time, but is also impractical for some applications such as roll-to-roll web processing where the workpieces are always present.

In vacuum depositions, it is desirable to have small source-to-workpiece area ratios to minimize wasted deposition on deposition sources. To increase productivity, it is also desirable to have multiple workpiece processed at same time. For web processing, it is desirable to have minimum contact with web handling equipment, such as rollers. For some applications, multiple processing steps are carried out in the same system, the earlier processing step can produce an intermediate deposited microstructure, which are strengthened by depositing thick films in later depositing steps. Any physical contact with the workpieces before the entire process is complete is detrimental to the workpieces.

There is therefore a need for PECVD system with high gas utilization, reduced gas phase reactions and powder formations, reduced deposition on deposition sources, increased lifetime of deposition sources, and increased system productivity.

### SUMMARY OF THE INVENTION

The present application discloses a high throughput deposition source and system for PECVD. Comparing to conventional systems, the disclosed source and system have higher gas utilization, reduced gas phase reactions and powder formations, reduced deposition on deposition sources, increased lifetime of deposition sources, minimized the process condition variation throughout source life time, reduced waste treatment, increased system productivity, and can eliminate physical contacts between workpieces and deposition system during processing.

In one general aspect, the present invention relates to a high throughput deposition apparatus that includes a vacuum chamber comprising a first processing chamber, a plurality of elongated deposition sources in parallel in the first processing chamber, wherein each of the elongated deposition sources can include a gas distribution channel configured to provide a deposition material in a gas form, and an electrode that can generate a plasma in the deposition material, and a web transport mechanism that can move a plurality of workpiece webs passing by the elongated deposition sources in the first processing chamber, wherein the plurality of workpiece webs can be parallel to each other and are configured to receive the deposition material in the first process chamber.

Implementations of the system may include one or more of the following. The web transport mechanism can include unwind reels and rollers configured to feed the plurality of workpiece webs, and rewind reels and rollers configured to redirect the plurality of workpiece webs. The high throughput deposition apparatus can further include: a first compartment configured to house the unwind reels and rollers; and a second compartment configured to house rewind reels and rollers. The plurality of workpiece webs can be only in contact with the unwind reels and rollers and the rewind reels and rollers. The elongated deposition sources can be plasma sources. At least one of the elongated deposition sources further comprises one or more magnets configured to confine the plasma. The elongated deposition sources can be substantially parallel to each other. The plurality of workpiece webs can be moved by the transport mechanism in a substantially vertical direction. The vacuum chamber can further include a second processing chamber and a second deposition source in the second processing chamber, wherein the web transport mechanism can further move the plurality of workpiece webs through the second processing chamber, wherein the plurality of workpiece web are configured to receive a second deposition material from the second deposition source in the second process chamber. The high throughput deposition apparatus can further include a first differential pumping chamber between the first processing chamber and the second processing chamber, wherein the web transport mechanism can further move the plurality of workpiece webs through the first differential pumping chamber. The vacuum chamber can further include a third processing chamber; and a second differential pumping chamber between the first processing chamber and the second processing chamber, wherein the web transport mechanism can further move the plurality of workpiece webs through the third processing chamber and the second differential pumping chamber.

In another general aspect, the present invention relates to a plasmas source that includes an elongated electrode that can be electrically biased at a first polarity; a gas distribution channel within the elongated electrode, the gas distribution channel that can provide a gas material, wherein a receiver is configured to be electrically biased at a second polarity thereby generating a plasma in the gas material; and one or more magnets that can confine the plasma, wherein the receiver is configured to receive material deposition from the plasma.

Implementations of the system may include one or more of the following. The plasmas source can further include a cooling channel in the elongated electrode, the cooling channel configured transport a cooling fluid to lower temperature of the elongated electrode. The gas distribution channel can be at least partially positioned inside the elongated electrode. The one or more magnets can be positioned inside the elongated electrode. The one or more magnets can be magnetized in along dimension of the elongated electrode.

In another general aspect, the present invention relates to a plasmas source that includes an elongated electrode that can be electrically biased at a first polarity, a gas distribution channel within the elongated electrode, the gas distribution channel that can provide a gas material, wherein a receiver is configured to be electrically biased at a second polarity thereby generating a plasma in the gas material, one or more magnets that can confine the plasma, wherein the receiver is configured to receive material deposition from the plasma, and a transport mechanism that can move a protective web over at least a portion of the elongated electrode, wherein the protective web can receive material deposition from the plasma and to prevent material deposition on the elongated electrode.

Implementations of the system may include one or more of the following. The transport mechanism can include a first reel configured to provide a new protective web and a second reel that can take up a protective web deposited with the deposition material. The transport mechanism can include a roller configured to turn around the protective web at an end of the elongated electrode. The plasmas source can further include a cooling channel in the elongated electrode. The cooling channel can transport a cooling fluid to lower temperature of the elongated electrode. The one or more magnets can be positioned inside the elongated electrode. The one or more magnets can be magnetized in along dimension of the elongated electrode.

These and other aspects, their implementations and other features are described in details in the drawings, the description and the claims.

### BRIEF DESCRIPTION OF THE DRAWINGS

FIGS. 1A and 1B are perspective views of a plasma source and workpieces compatible with a portion of a vacuum deposition system in accordance with the present invention.

FIG. 2 is perspective cross-sectional view of a plasma source compatible with the vacuum deposition system in FIGS. 1A and 1B.

FIGS. 3A-3C are respectively perspective and cross-sectional views of a plasma source comprising a protective web and associated mechanism compatible with the vacuum deposition system in FIGS. 1A and 1B.

FIGS. 4A-4C are perspective views of a vacuum deposition system in accordance with the present invention.

FIGS. 5A-5C are perspective views showing details of a substrate transport mechanism in a vacuum deposition system in accordance with the present invention.

### DETAILED DESCRIPTION OF THE INVENTION

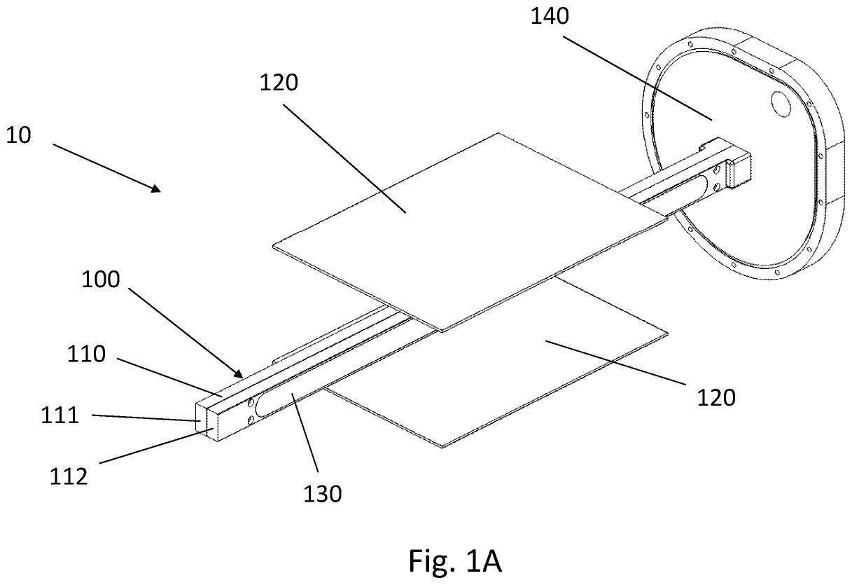

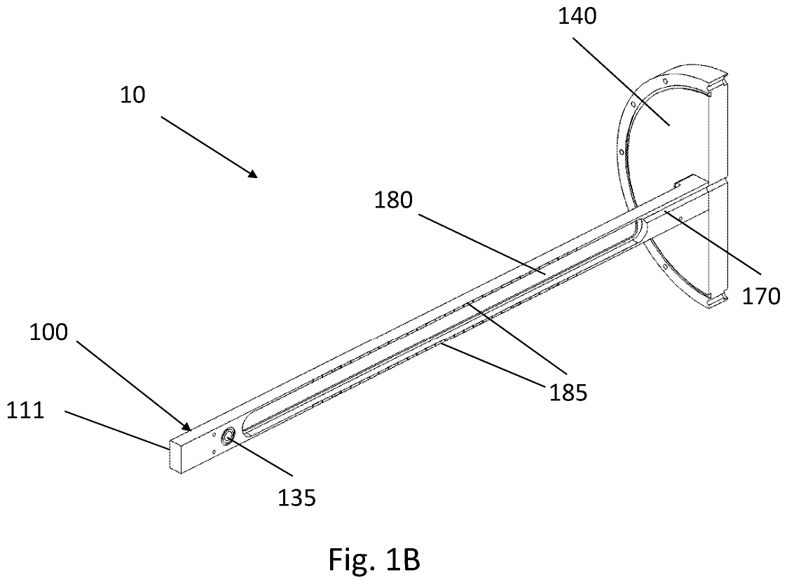

FIGS. 1A and 1B show a portion of a vacuum deposition system 10 comprising a deposition source such as a plasma source 100, and one or more workpieces 120, which are placed inside a vacuum chamber (not shown). The deposition source such as the plasma source 100 has an elongated shape, which includes an electrode 110 in elongated shape. The one or more workpieces 120 are positioned on one side or multiple sides of the electrode 110, all inside the vacuum chamber (not shown) in which the atmosphere gases are evacuated and back filled with desirable gases such as argon, Silane, nitrogen, et al.

In operation, a voltage such as radio frequency (RF) power is applied between workpieces and the electrode and a plasma is formed with aid of the back filled gases. Unlike conventional parallel-plate PECVD sources which includes a pair of counter electrodes (a cathode and an anode), the disclosed plasma source 100 only includes an electrode with one polarity (a cathode or an anode); there is no dedicated counter electrode. Instead, the one or more workpieces 120 are electrically biased relative to the electrode 110 to perform the function of a counter electrode. The one or more workpieces 120 are configured to receive material depositions. In some cases, such as the web are electrically insulators or the deposited films are thick insulators, or to optimize plasma density, separate counter electrodes can be placed near electrode 110 to form plasma.

The electrode 110 can be made of two electrode pieces 111, 112 each including its own liquid cooling channel 130 welded in and with its own gas distribution channel. Two electrode pieces 111, 112 can be bolted together and attached to a mounting flange 140 with screws and bolts. O-ring seals can be used to ensure the vacuum integrity in the vacuum chamber (not shown). The mounting flange 140 can be made of insulating materials such as TEFLON or PEEK to ensure electrical isolations of the electrode 110 from the vacuum chamber (not shown) and the workpieces 120. In one implementation, the mounting flange 140 can be mounted to the vacuum chamber (not shown) of the vacuum deposition system 10.

The cooling channels 130 in the electrode pieces 111, 112 can be connected through a cooling channel interface 135 with O-ring seal as seen in the cross-sectional view of FIG. 1B. A gas inlet 170 can accept processing gases through the mounting flange 140 and evenly distribute the gases via a gas distribution channel 180 along the length of the electrode 110. Small gas distribution holes 185 can be drilled or machined into the electrodes 110 to ensure even distribution or optimized distribution of gases.

In operation, a voltage such as radio frequency (RF) power is applied between workpieces 120 and the electrode 110. In PECVD, a plasma is formed with aid of the back filled gases. The plasma breaks up the gases in the vacuum chamber (not shown) and deposit materials on the workpieces 120. In some embodiments, in case of plasma etch or cleaning, the plasma breaks up the gases to etch the workpieces 120 and the electrode 110 in the vacuum chamber (not shown). The operation pressure in the vacuum chamber (not shown) can be kept between tens of Millitorr to tens of Torrs when radio frequency (RF) power is applied between the electrode 110 and the workpieces 120.

The disclosed plasma source has the advantage of having small electrode areas to maximize deposition on workpieces, simple design, and can process multiple workpieces at same time. The presently disclosed plasma source also allows easy cleaning of the electrode and channels and holes for gas distribution.

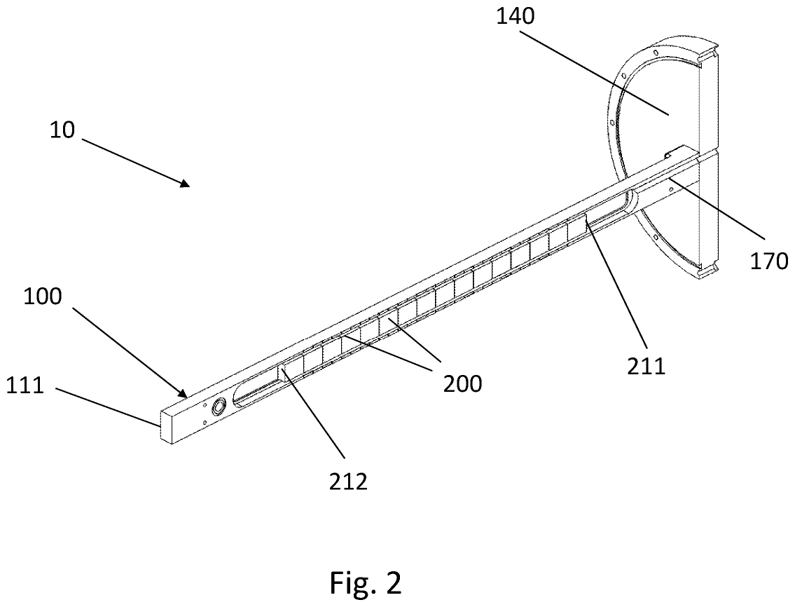

In some embodiments, referring to FIG. 2, magnets 200 can be placed inside the electrode 110 (or one of the electrode pieces 111, 112) in the vacuum deposition system 10. The magnets 200 can be formed by one piece or multiple pieces where the distribution and magnetic strength can be optimized to achieve the desirable deposition properties. When the magnets 200 can be permanent magnets magnetized along the long axis with the north pole 211 and the south pole 212 as shown, the magnet field is substantially parallel to long dimension of the electrode piece 111 to confine the plasma generated by the electric bias voltage. The electrons in the plasma are trapped by Lorentz force; hopping around the electrode 110, which can greatly enhance the plasma density and lower the required operating pressure. Our tests show that the operating pressure can be less than 1 Millitorr. Since gas phase reactions are approximately proportional to the square of the reactive gas pressure, lowered gas pressure significantly reduces gas waste and powder formation. Gas utilization is greatly increased. The magnet poles polarities (the north pole 211 and the south pole 212) can be reversed to achieve the same effect. Other magnetic field configurations are possible to optimize the process.

Referring to FIGS. 1A-2, the disclosed vacuum deposition system 10 can be implemented in different types of vacuum depositions: webs, plates, curved surfaces, and wafers. In PECVD, the gas distribution channels can be machined next to the magnets 200 to ensure uniformity.

In PECVD, materials are deposited on all surfaces that are exposed to plasma. The disclosed vacuum deposition system 10 minimizes the surface area of the electrode 110 and maximizes the percentage of deposition on the workpieces 120 to increase material utilization. However, thick materials can still be deposited on the deposition sources over time. Thick material deposition on the electrode 110 can lead to particulate formation, flaking off of the deposited materials, a change of plasma conditions over time, and clogging of the gas distribution holes 185. Plasma cleaning can be used to reduce these effects, but may not be practical in some cases such as a web formed workpieces, which has a portion always exposed to plasma.

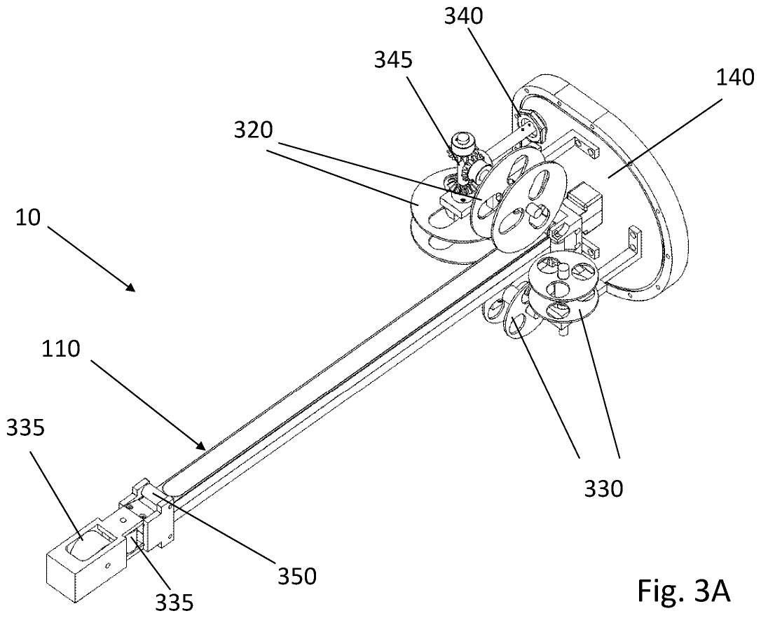

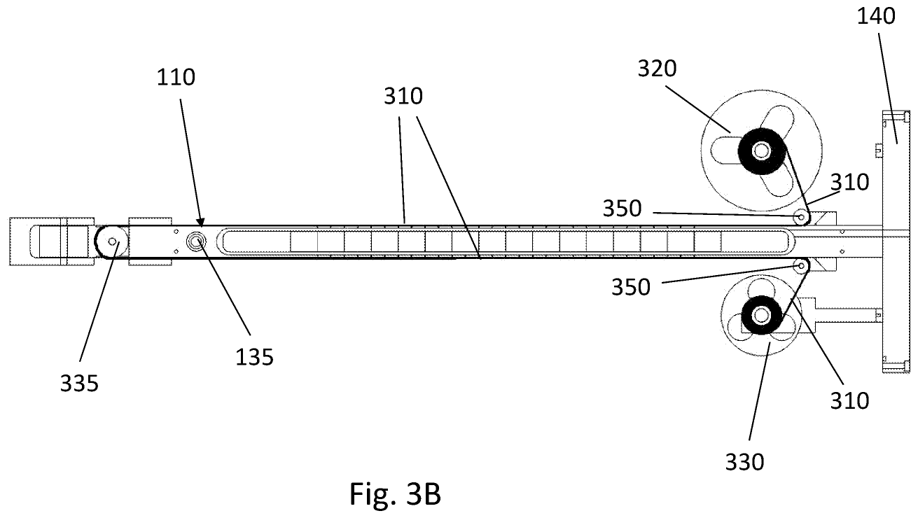

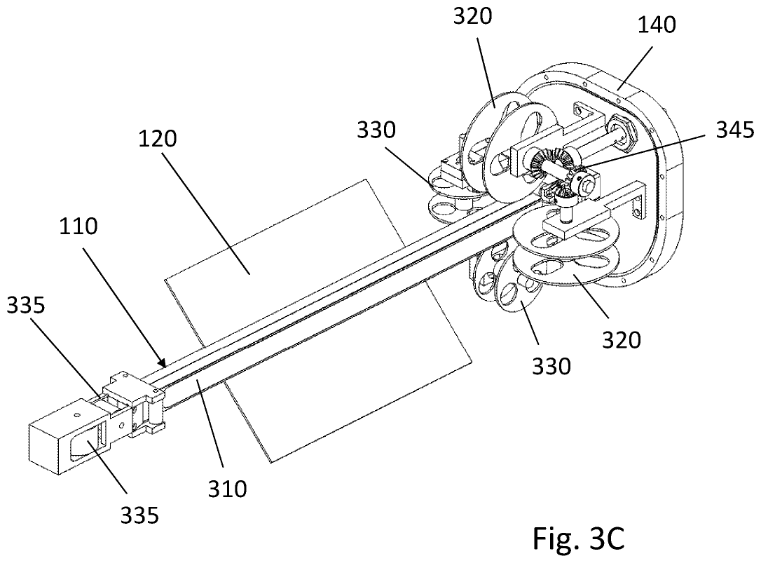

In some embodiments, as shown in FIGS. 3A and 3B, surfaces of the electrode 110 can be covered with one or more protective webs 310 that are continuously or periodically moved from new web reels 330 to storage reels 320 and can collect materials deposited towards the electrode 110. The materials collected on the protective web 310 are stored in storage reels 320. The new web reels 330 provide a fresh protective web 310. After deposition on the protective web 310, the storage reels 320 takes the protective web 310 with deposited materials from the new web reels 330 and store it.

The two storage reels are driven by one or two separate motors 340 outside the mounting flange 140 through a rotational vacuum feed through and a set of angular gears 345 in this embodiment. Other means of rotating the storage reels are also possible. The new web reels 330 can be attached to active or passive tension devices such as slippage clutch or motors to control the tension of the protective webs 310. With aid of at least two turn around rollers 335 and guiding rollers 350, the protect webs 310 can cover all 4 surfaces of the electrode.

FIG. 3B shows the protective webs 310 driven by guiding rollers 350. The length of the protective web 310 can be more than a few hundred times longer than the length of the electrode 110, thus increasing the effective lifetime of the electrode 110 by more than a few hundreds of times. During system maintenance, the protective webs 310 with material deposition are removed either with or without the storage reels 320. A fresh protective web 310 is installed to the new web reel 330 or another new web reel 330 with fresh protective web 310 replaces the existing new web reel 330. The fresh protective web 310 is then threaded through various guiding rollers and turn-around rollers 335 and connected to the storage reels 320. A single protective web 310 can also be used to protect all 4 sides of the electrode 110 by making single or multiple turns at both ends of the electrode 110. Only one un-wind reel and one storage reel are required in this case.

Referring to FIG. 3C, the protective web 310 can reach significant thickness as it moves over the electrode 110. The variation in thickness may cause non-uniformity in gas distribution and plasma. One way is to orient the workpieces 120 so that the workpieces 120 are exposed equally to two protective webs 310 on two sides of the electrode 110. The protective web 310 in one side is before a turn-around roller 335 and the protective web 310 on other side is after the turn-around roller 335, so that the average thickness on the two protective webs 310 is uniform across the length of the electrode 110.

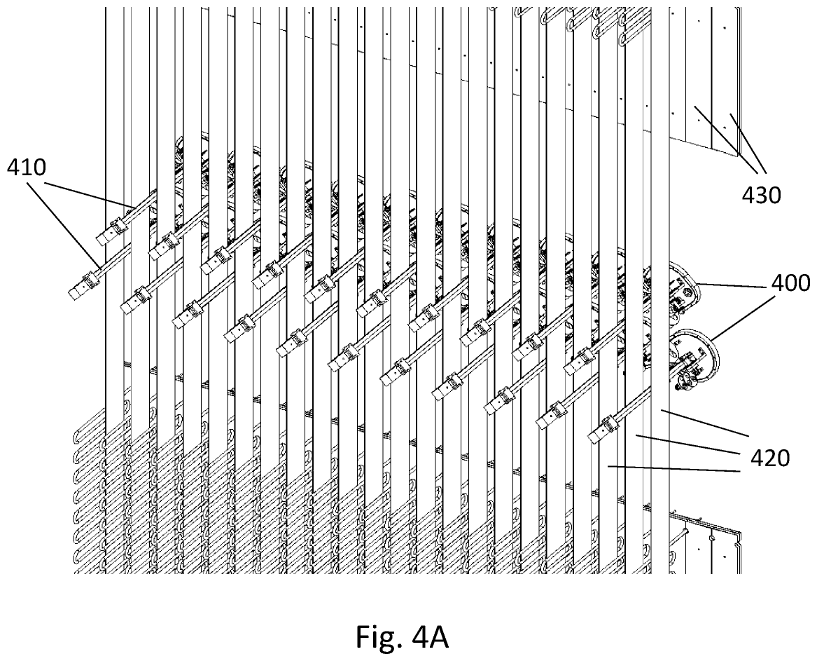

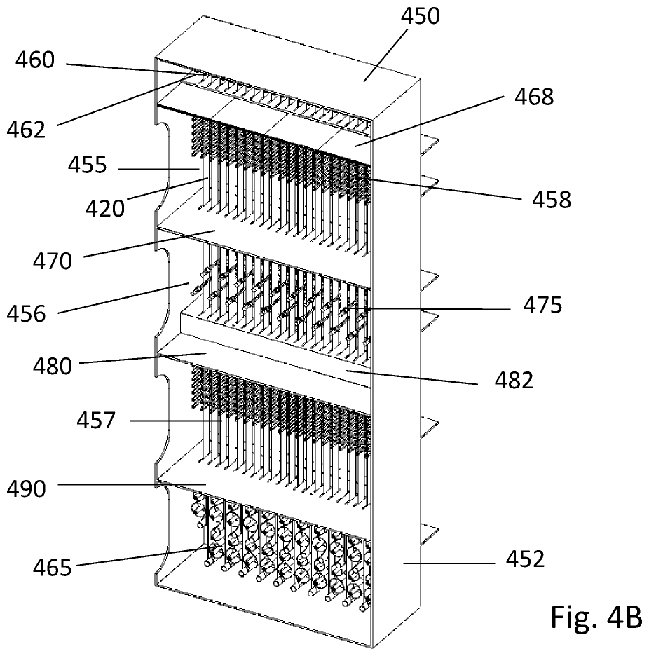

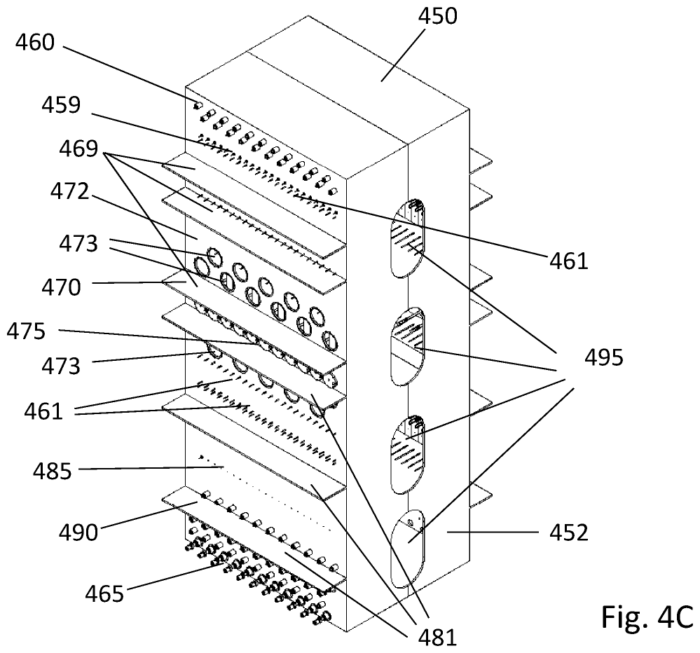

Referring to FIG. 4A, due to the small dimensions of the disclosed electrodes, multiple electrodes 410 and multiple workpieces 420 can be placed in parallel to increase system throughput. The electrodes 410 are associated with multiple elongated plasma sources 400, which are positioned substantially in parallel. The workpieces 420 are transported passing by the elongated plasma sources 400. The elongated plasma sources 400 can process multiple workpieces 420 at the same time. The same vacuum envelope can hold multiple electrodes 410 to save cost and also to further enhance the gas material utilization since the gases can be ionized multiple times before they are pumped out. The workpieces 420 can be in the form webs, or solid plates. The vacuum envelope can include thermal shields 430.

In some embodiments, referring to FIG. 4B, a vacuum process system 450 can include a vacuum chamber 452 and multiple process chambers (or stations) 455, 456, 457 therein. Each of process chambers (or stations) 455, 456, 457 can house multiple electrodes 410 and workpieces 420. The workpieces 420 can be in a web form that can be transported through the different process chambers 455, 456, 457. The webs of workpiece 420 are moved passing by the electrodes 410. The web transport mechanism can include un-wind reels and rollers 460 on top, and the re-wind reels and rollers 465 and interleaf reels (not shown) at the lower compartment in the vacuum chamber 452.

The un-wind reels and rollers 460 in the upper compartment and the process chamber 455 are separated by separation plates 468. The process chamber 455 below the unwind rollers include a thermal CVD zone including heaters 458. The process chamber 456 can include a PECVD process zone. The process chamber 455 and the process chamber 456 are separated by separation plates 470 and one or more differential pumping chambers 472 (hidden from view). The process chamber 456 and the process chamber 457 are separated by separation plates 480 and one or more differential pumping chambers 482. The process chamber 457 and the re-wind reels and rollers 465 in the lower compartment are separated by separation plates 490. The separation plates 468 and 480 are mainly used to cool the upper and lower compartment to prevent deposition and do not create significant pressure differentials.

One advantage of the disclosed vacuum process systems is that there is no physical contact between the deposition surfaces of the workpieces and the components in the deposition system through the processing steps. The webs of workpieces 420 are only in contact with the un-wind reels and rollers 460 and the re-wind reels and rollers 465. The webs of workpieces can be substantially vertically aligned so they are free of gravity-caused deformation. The web transport mechanism can thus be simplified without the need for rollers to support the web in the process steps.

FIG. 4C shows the outside view of the vacuum process system 450. Referring to FIGS. 4B and 4C, there are plates 470, 480, 490 separating different process chambers and doors (not shown) to seal the openings to the various process chambers. The maintenance openings 495 are respectively provided for each process chamber to allow maintenance personnel to access each chambers to perform cleaning, replacement and maintenance. The separation plates 470, 480, 490 serve as the mechanical support for maintenance personnel and also to reduce the deformation of the system caused by vacuum force. The first process chamber 455 can include a gas inlet 459 and heater feed through 461. The pumping chambers 472, 482 include pumping ports 473. The process chamber 456 can include substantially parallel elongated plasma sources 475 for PECVD. The third process chamber 457 can include a gas inlet 485. Plates 469 and 481 are welded to the vacuum system 450 to reduce the deflection due to vacuum forces.

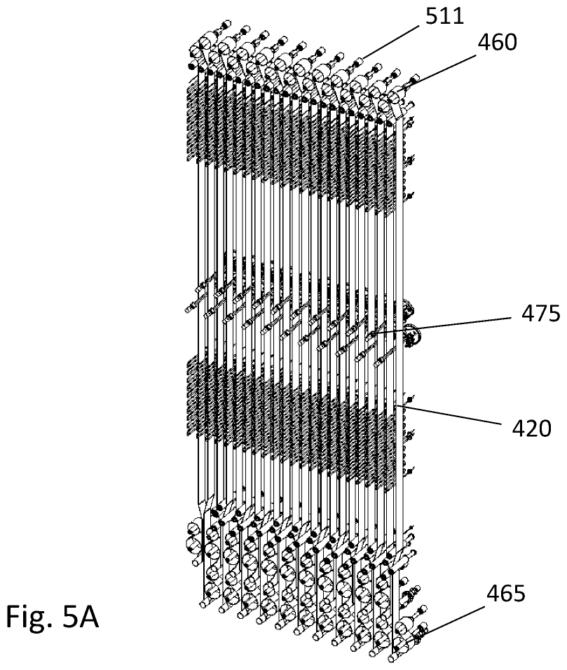

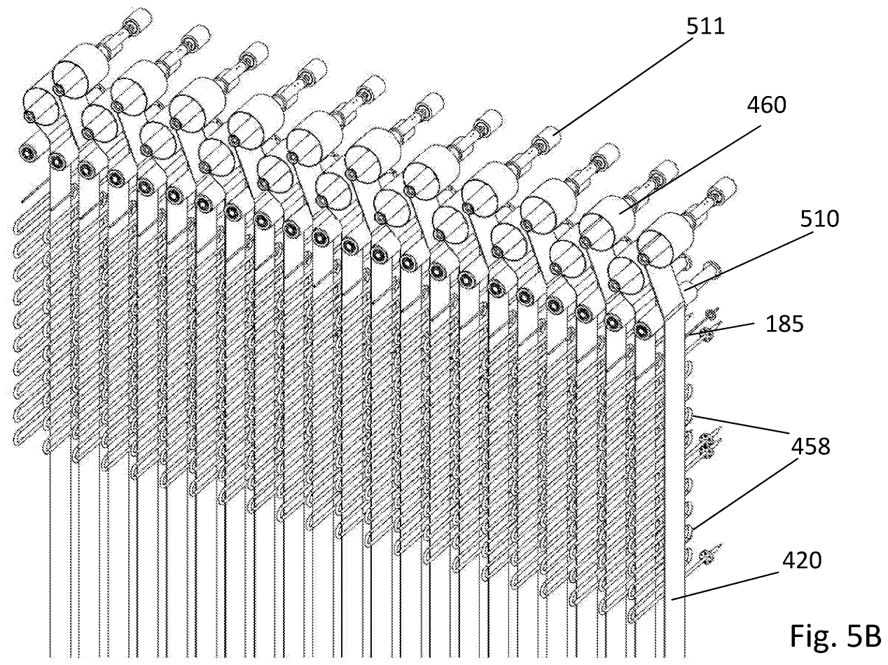

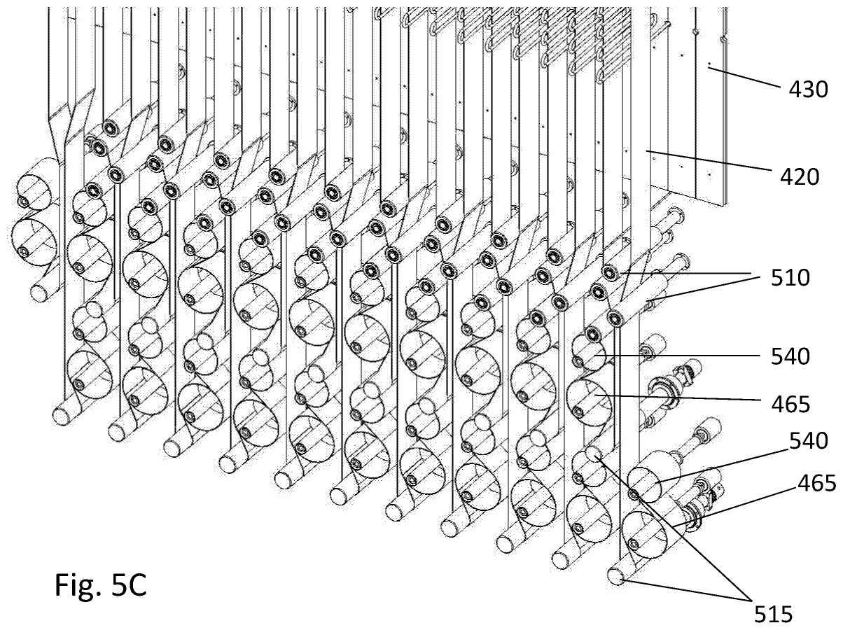

In some embodiments, FIG. 5A shows the internal components of the vacuum process system 450 (FIGS. 4B and 4C) without the vacuum envelope for clarity. FIG. 5B shows the upper compartment of such internal components. Referring to FIGS. 5A. 5B, and 4B and 4C, the new webs of workpieces 420 are mounted to un-wind reels 460. The shafts of the un-wind reels 460 are connected to motors outside the vacuum chamber 452 through rotational vacuum feed through 511. Idler rollers 510 guide the web of workpieces 420 to keep the web positions to stay the same in the process chambers. The idler rollers 510 are mounted inside the vacuum chamber 452 and no feed-through is necessary. The webs of workpieces 420 go through slits on the top shelf plate 462 and to the first process chamber 455. The top shelf plate 462 improves the structure integrity of the vacuum chamber 452, provides cooling to avoid CVD deposition on the un-wind reels and rollers 460; and serves as mounting base for thermal shields 468.

The webs are heated by heaters 458 to desired temperature. A series of gas distribution lines 185 flow gases into the first process chamber 455 in a uniform fashion. Optionally, gas distribution channels can be machined or/and welded in the top shelf plate 462. The top shelf plate 462, the separation plates 470, 480, 490, and the vacuum chamber 452 can be cooled so that the top un-wind reels and rollers 460 and bottom re-wind reels and rollers 465 are at low temperature to avoid deposition.

Multiple sheet metals can be mounted to the vacuum chamber 452 and the separation plates 470, 480, 490 to reduce heat loss and keep the vacuum chamber 452 and the separation plates 470, 480, 490 cool. FIG. 4B shows some of the thermal shields 468 to protect the unwind reels and rollers 460 in the top compartment. FIG. 4A shows some of the thermal shields 430 to protect the vacuum chamber 452.

The first process chamber 455 can have its own pumping ports, or be pumped by the pumps in the differential pump chamber through the slits in the first separation plate. The differential pump chamber is a box with slits on top and bottom to allow the webs of workpieces 420 to go through. The box can have a removable side cover to allow cleaning and service. There are optional plates inside the differential pumping box with slits to allow the webs of workpieces 420 to go through and separate the box into multiple differential pumping chambers, each with its own set of pumps, to further isolate the first process chamber and the second processing chamber (e.g. PECVD).

Once the webs of workpieces 420 enter a PECVD process chamber (e.g. the process chamber 456), the deposition sources form plasma with the voltage biased webs of workpieces 420 as described above in discussion with FIGS. 1A-2. The deposition source can be powered by the same power supply if the power distribution is stable and evenly distributed between various deposition sources. Otherwise separate power supplies can be used to drive each or groups of deposition sources separately. RF waves can be triggered by the same input signal to ensure the phases of various RF power supplies are synchronized. The web is typically electrically connected to the vacuum chamber 452 for simplicity but can be isolated electrically. The PECVD process chamber can have its own pumps to increase the pumping rate, gas flow rate and deposition rate.

After PECVD deposition, the webs of workpieces 420 can enter optional or additional process chambers. There may be one or more differential pumping chambers 455-457 to isolate the process chambers 455-457. After all processes are finished, the webs may be wound to re-wind reels and rollers 465 through idler rollers 510 in a lower compartment. Referring to FIG. 5C, some of the idlers 515 may be liquid cooled to ensure low temperature of the web. Interleafs may be added to reduce mechanical damages during re-wind. Since there may be significant deposition thickness and additional interleaf reels 540, the re-wind roll diameter may be much larger than the un-wind reels and rollers 465. FIG. 5C shows the available space for the re-wind reels and rollers 465 can be increased by grouping two or more webs and its rollers into a narrow strip of space.

In case of a rectangular-shaped vacuum envelope (or chamber), the webs of workpieces at the end of the array may only see deposition on one side during PECVD, if there is no deposition source at outer side of the workpiece web array, as shown in FIG. 4A. There may be applications where single side deposition on webs of workpieces is still useful. In some embodiments, there can be more deposition sources than the web of the workpiece, so each web sees coating on both sides. In case only one side of the web of workpiece or rigid workpieces needs to be coated, the web can be placed back to back with its neighboring web and/or eliminate half of the deposition sources.

The arrays of deposition sources and webs can be doubled by placing identical arrays on the opposite side of the vacuum envelope. In some case, arrays of deposition sources can be installed on a third wall or even a fourth wall of the vacuum chamber. The vacuum chamber can be shaped like polygon with more than 4 sides.

Only a few examples and implementations are described. Other implementations, variations, modifications and enhancements to the described examples and implementations may be made without deviating from the spirit of the present invention. For example, the disclosed deposition apparatus are compatible with other spatial configurations for the substrate, the deposition source, and substrate movement directions than the examples provided above. The PECVD sources can be of different types and configurations for the system.

What is claimed is:

1. A high throughput deposition apparatus, comprising:
a vacuum chamber comprising a first processing chamber;
a plurality of elongated deposition sources in parallel in the first processing chamber, wherein each of the elongated deposition sources comprises a gas distribution channel configured to provide a deposition material in a gas form, and an electrode configured to generate a plasma in the deposition material; and
a web transport mechanism configured to move a plurality of workpiece webs each passing by at least one of the plurality of elongated deposition sources in the first processing chamber, wherein the plurality of workpiece webs are parallel to each other and are configured to receive the deposition material in the first process chamber.

2. The high throughput deposition apparatus of claim 1, wherein the web transport mechanism comprises unwind reels and rollers configured to feed the plurality of workpiece webs, and rewind reels and rollers configured to redirect the plurality of workpiece webs,
the high throughput deposition apparatus further comprising:
a first compartment configured to house the unwind reels and rollers; and
a second compartment configured to house rewind reels and rollers.

3. The high throughput deposition apparatus of claim 2, wherein the plurality of workpiece webs are only in contact with the unwind reels and rollers and the rewind reels and rollers.

4. The high throughput deposition apparatus of claim 1, wherein the elongated deposition sources are plasma sources.

5. The high throughput deposition apparatus of claim 4, wherein at least one of the elongated deposition sources further comprises one or more magnets configured to confine the plasma.

6. The high throughput deposition apparatus of claim 1, wherein the elongated deposition sources are substantially parallel to each other.

7. The high throughput deposition apparatus of claim 1, wherein the plurality of workpiece webs are moved by the transport mechanism in a substantially vertical direction.

8. The high throughput deposition apparatus of claim 1, wherein the vacuum chamber further comprises a second processing chamber and a second deposition source in the second processing chamber,
wherein the web transport mechanism is further configured to move the plurality of workpiece webs through the second processing chamber, wherein the plurality of workpiece web are configured to receive a second deposition material from the second deposition source in the second process chamber.

9. The high throughput deposition apparatus of claim 8, further comprising:
a first differential pumping chamber between the first processing chamber and the second processing chamber,
wherein the web transport mechanism is further configured to move the plurality of workpiece webs through the first differential pumping chamber.

10. The high throughput deposition apparatus of claim 1, wherein the vacuum chamber further comprises a third processing chamber; and
a second differential pumping chamber between the first processing chamber and the second processing chamber,
wherein the web transport mechanism is further configured to move the plurality of workpiece webs through the third processing chamber and the second differential pumping chamber.

11. A plasmas source, comprising:
an elongated electrode configured to be electrically biased at a first polarity;
a gas distribution channel within the elongated electrode, the gas distribution channel configured to provide a gas material, wherein a receiver is configured to be electrically biased at a second polarity thereby generating a plasma in the gas material; and
one or more magnets configured to confine the plasma, wherein the receiver is configured to receive material deposition from the plasma.

12. The plasmas source of claim 11, further comprising:
a cooling channel in the elongated electrode, the cooling channel configured transport a cooling fluid to lower temperature of the elongated electrode.

13. The plasmas source of claim 11, wherein the gas distribution channel is at least partially positioned inside the elongated electrode.

14. The plasmas source of claim 11, wherein the one or more magnets are positioned inside the elongated electrode.

15. The plasmas source of claim 11, wherein the one or more magnets are magnetized in along dimension of the elongated electrode.

16. A plasmas source, comprising:
an elongated electrode configured to be electrically biased at a first polarity;
a gas distribution channel within the elongated electrode, the gas distribution channel configured to provide a gas material, wherein a receiver is configured to be electrically biased at a second polarity thereby generating a plasma in the gas material;
one or more magnets configured to confine the plasma, wherein the receiver is configured to receive material deposition from the plasma; and
a transport mechanism configured to move a protective web over at least a portion of the elongated electrode, wherein the protective web is configured to receive material deposition from the plasma and to prevent material deposition on the elongated electrode.

17. The plasmas source of claim 16, wherein the transport mechanism includes a first reel configured to provide a new protective web and a second reel configured to take up a protective web deposited with the deposition material.

18. The plasmas source of claim 16, wherein the transport mechanism includes a roller configured to turn around the protective web at an end of the elongated electrode.

19. The plasmas source of claim 16, further comprising:
a cooling channel in the elongated electrode, the cooling channel configured transport a cooling fluid to lower temperature of the elongated electrode.

20. The plasmas source of claim 16, wherein the one or more magnets are positioned inside the elongated electrode.
